(19) United States
(12) Patent Application Publication
(10) Pub. No.: US 2010/0090321 A1
(43) Pub. Date: Apr. 15, 2010

(54) HIGH-K ETCH STOP LAYER OF REDUCED THICKNESS FOR PATTERNING A DIELECTRIC MATERIAL DURING FABRICATION OF TRANSISTORS

(76) Inventors: Robert Mulfinger, Dresden (DE); Andy Wei, Dresden (DE); Roman Boschke, Dresden (DE); Casey Scott, Dresden (DE)

Correspondence Address: Advanced Mirco Devices, Inc.;c/o Williams, Morgan & Amerson, 10333 Richmond, Suite 1100, Houston, TX, 77042, US

(21) Appl. No.: 12/248,971

(22) Filed: Oct. 10, 2008

(51) Int. Cl. H01L 23/58; H01L 21/311

(52) U.S. Cl. 257/632; 438/694; 257/E23.002; 257/E21.249

(57) ABSTRACT

By providing a high-k dielectric etch stop material as an etch stop layer for patterning an interlayer dielectric material, enhanced performance and higher flexibility may be achieved since, for instance, an increased amount of highly stressed dielectric material may be positioned more closely to the respective transistors due to the reduced thickness of the high-k dielectric etch stop material.

### BACKGROUND

1. Field of the Disclosure

Generally, the present disclosure relates to the field of integrated circuits, and, more particularly, to field effect transistors and manufacturing techniques on the basis of dielectric layers used for forming sophisticated transistor structures, such as transistors requiring high strain levels in the channel region.

2. Description of the Related Art

Integrated circuits are typically comprised of a large number of circuit elements located on a given chip area according to a specified circuit layout, wherein, in complex circuits, the field effect transistor represents one predominant circuit element. Generally, a plurality of process technologies for advanced semiconductor devices are currently practiced, wherein, for complex circuitry based on field effect transistors, such as microprocessors, storage chips and the like, CMOS technology is currently one of the most promising approaches due to the superior characteristics in view of operating speed and/or power consumption and/or cost efficiency. During the fabrication of complex integrated circuits using CMOS technology, millions of complementary transistors, i.e., N-channel transistors and P-channel transistors, are formed on a substrate including a crystalline semiconductor layer. A field effect transistor, irrespective of whether an N-channel transistor or a P-channel transistor is considered, comprises so-called PN junctions that are formed by an interface of highly doped drain and source regions with an inversely or weakly doped channel region disposed between the drain region and the source region. The conductivity of the channel region, i.e., the drive current capability of the conductive channel, is controlled by a gate electrode formed above the channel region and separated therefrom by a thin insulating layer. The conductivity of the channel region, upon formation of a conductive channel due to the application of an appropriate control voltage to the gate electrode, depends on the dopant concentration, the mobility of the majority charge carriers and, for a given extension of the channel region in the transistor width direction, on the distance between the source and drain regions, which is also referred to as channel length. Hence, in combination with the capability of rapidly creating a conductive channel below the insulating layer upon application of the control voltage to the gate electrode, the conductivity of the channel region substantially determines the performance of the MOS transistors. Thus, the reduction of the channel length, and associated therewith the reduction of the channel resistivity, may be a dominant design criterion for accomplishing an increase in the operating speed of the integrated circuits.

The shrinkage of the transistor dimensions, however, involves a plurality of issues associated therewith that have to be addressed so as to not unduly offset the advantages obtained by steadily decreasing the channel length of MOS transistors. One issue is the requirement for patterning features of reduced size on the basis of advanced lithography techniques in combination with complex etch processes. That is, typically, material layers, such as dielectric materials, semiconductive materials, metals and the like, have to be deposited and subsequently patterned into device features by using appropriate etch masks. For example, photoresist material may frequently be used as an etch mask, wherein the resist is patterned in turn by exploiting the photo chemical characteristics of the resist material so as to form a latent image in the resist, which may then be “etched” or developed to remove unwanted portions of the resist material. The resulting mask may then be used as a template for etching the underlying material so as to transfer the mask feature into the underlying material layer with a degree of fidelity that depends on the etch ambient used for the etch process. In order to allow a reproduction of the mask feature with an adjustable degree of sidewall angle of the etched feature, plasma-assisted “dry” etch techniques have been developed, in which a plasma ambient is established on the basis of a reactive gas component. The particles react with the surface to be etched, wherein, typically, the ambient may cause a different removal rate for different materials that are in contact with the reactive plasma ambient. Moreover, the ions may be accelerated towards the surface to be etched, thereby also imparting a “physical” component to the removal rate, which contributes to increased directionality of the removal process. In addition, appropriate polymer substances may be added, which may also allow an adjustment of the directionality of the etch front, thereby enabling a highly “anisotropic” etch behavior. The mechanism of plasma etching depends on the capability of the reactive component to form a volatile etch byproduct which is released into the ambient, thereby increasingly removing material from the exposed surface. Frequently, it is important to protect deeper lying materials from exposure to the plasma ambient or a defined depth for stopping the etch process across the entire surface may be required, which is typically accomplished by providing an etch stop layer, which is to be understood as a material having a significantly reduced removal rate compared to the material that is actually to be etched in the plasma ambient.

However, with ever decreasing feature sizes, the deposition of material layers above pronounced surface topographies may require reduced layer thickness of the actual material layers and in particular of etch stop layers.

Another issue associated with reduced gate lengths is the occurrence of so-called short channel effects, which may result in a reduced controllability of the channel conductivity. Short channel effects may be countered by certain design techniques, some of which, however, may be accompanied by a reduction of the channel conductivity, thereby partially offsetting the advantages obtained by the reduction of critical dimensions.

In view of this situation, it has been proposed to enhance device performance of the transistor elements not only by reducing the transistor dimensions but also by increasing the charge carrier mobility in the channel region for a given channel length, thereby increasing the drive current capability and thus transistor performance. For example, the lattice structure in the channel region may be modified, for instance, by creating tensile or compressive strain therein, which results in a modified mobility for electrons and holes, respectively. For example, creating tensile strain in the channel region of a silicon layer having a standard crystallographic configuration may increase the mobility of electrons, which, in turn, may directly translate into a corresponding increase of the conductivity of N-type transistors. On the other hand, compressive strain in the channel region may increase the mobility of holes, thereby providing the potential for enhancing the performance of P-type transistors.

One efficient approach in this respect is a technique that enables the creation of desired stress conditions within the channel region of different transistor elements by adjusting the stress characteristics of a dielectric layer stack that is formed above the basic transistor structure. The dielectric layer stack typically comprises one or more dielectric layers which may be located close to the transistor and which may also be used in controlling a respective etch process in order to form contact openings to the gate and drain and source terminals. Therefore, an effective control of mechanical stress in the channel regions, i.e., effective stress engineering, may be accomplished by individually adjusting the internal stress of these layers, which may also be referred to as contact etch stop layers, and by positioning a contact etch stop layer having an internal compressive stress above a P-channel transistor while positioning a contact etch stop layer having an internal tensile strain above an N-channel transistor, thereby creating compressive and tensile strain, respectively, in the respective channel regions.

Typically, the contact etch stop layer is formed by plasma enhanced chemical vapor deposition (PECVD) processes above the transistor, i.e., above the gate structure and the drain and source regions, wherein, for instance, silicon nitride may be used, due to its high etch selectivity with respect to silicon dioxide, which is a well-established interlayer dielectric material. Furthermore, PECVD silicon nitride may be deposited with a high intrinsic stress, for example, up to 2 Giga Pascal (GPa) or significantly higher of compressive stress and up to 1 GPa and significantly higher of tensile stress, wherein the type and the magnitude of the intrinsic stress may be efficiently adjusted by selecting appropriate deposition parameters. For example, ion bombardment, deposition pressure, substrate temperature, gas flow rates and the like represent respective parameters that may be used for obtaining the desired intrinsic stress.

During the formation of the two types of stressed layers, conventional techniques may suffer from reduced efficiency when device dimensions are increasingly scaled by using the 45 nm technology and even further advanced approaches, due to the limited conformal deposition capabilities of the deposition processes involved, which may result in respective process non-uniformities during subsequent process steps for patterning the stressed layer and forming contact openings, as will be explained in more detail with reference to FIGS. 1a-1b.

FIG. 1a schematically illustrates a cross-sectional view of a semiconductor device 100 in a certain manufacturing stage for forming stress-inducing layers above a plurality of first transistors 150A and second transistors 150B. The transistors 150A, 150B may be formed above a substrate 101, above which is positioned a semiconductor layer 102, such as a silicon-based layer, which may be separated from the substrate 101 by a buried insulating layer (not shown) if a silicon-on-insulator (SOI) configuration is considered. In the example shown, the transistor elements 150A, 150B may comprise a gate electrode 151 which may be formed on a gate insulation layer 152, which separates the gate electrode 151 from a channel region 153. The channel region is located between drain and source regions 154, which may be represented by any appropriate dopant species and dopant profile according to the specific design considerations for the transistors 150A, 150B. For example, the transistors 150A may represent transistor elements formed in a device region of a high packing density, such as RAM (random access memory) areas in sophisticated semiconductor devices and may represent transistors of the same conductivity type, for instance, N-channel transistors, while the transistor 150B may represent a transistor of a different conductivity type, such as a P-channel transistor. Thus, respective design rules may have to be applied during the formation of the semiconductor device 100 to obtain the transistors 150A, 150B with appropriate dimensions in order to achieve the desired overall performance of the device 100, as previously explained. For example a gate length, i.e., in FIG. 1a, the horizontal extension of the gate electrodes 151, may be approximately 50 nm and less in sophisticated applications. Furthermore, depending on the overall device configuration, the transistors 150A may further comprise a spacer structure 155, formed on sidewalls of the gate electrodes 151. Additionally, metal silicide regions 156 may be formed in the drain and source regions and possibly in the gate electrodes 151, depending on the overall design of the transistors 150A, 150B.

As previously discussed, transistor performance may be enhanced for a given design length of the transistor dimensions by creating a specified type of strain in the respective channel regions 153, which may frequently be accomplished by providing a highly stressed dielectric material above the basic transistor structure, as shown in FIG. 1a. For this purpose, in the manufacturing stage shown, a dielectric layer 130 may be formed above the transistors 150A, 150B, wherein a high internal stress level of the layer 130 may be selected such that, for instance, performance of the transistors 150A may be enhanced. For example, if the transistors 150A represent N-channel transistors, a high tensile stress level may be generated in the layer 130, which may also be transferred into the channel regions 153 by creating a desired tensile strain in the transistors 150A and also in the transistor 150B, in which a corresponding tensile strain, however, may not be desirable. Consequently, a portion of the layer 130 located above the transistor 150B has to be removed on the basis of advanced plasma-assisted etch techniques. As previously explained, for an efficient control of the respective plasma-assisted etch process and in view of protecting sensitive device areas of the transistor 150B, an etch stop layer 131 is typically provided that has reduced etch rate with respect to a specific plasma-assisted etch recipe compared to the material of the layer 130. In view of suppressing any undue damage of the transistor 150B, a thickness of the etch stop layer 131 may have to be selected such that a reliable stop of the etch front may be realized within the layer 131, while also providing sufficient process margin for accommodating etch non-uniformities across the substrate 101 during a plasma-assisted etch process.

During a process sequence for forming the semiconductor device 100, which may include well-established process techniques for forming the transistors 150A, 150B in accordance with standard CMOS techniques, the etch stop layer 131 is deposited, for instance, on the basis of plasma-assisted chemical vapor deposition (CVD), wherein a thickness is selected such that the desired etch stop capability may be provided. For instance, silicon dioxide is a well-established stop material with respect to a silicon nitride material during well-established plasma-assisted etch recipes, wherein a thickness may be selected to be 20 nm and more, depending on the desired degree of process fluctuations that may have to be taken into consideration. Next, the strain-inducing layer 130 may be deposited, for instance, as a silicon nitride material having the desired high internal stress level. It turns out, however, that, sophisticated device geometries created by the height of the gate electrodes 151 and the distance between closely spaced gate electrode structures may impose significant constraints on the respective deposition recipes. That is, process parameters for the PECVD process for forming the layer 130 may have to be adapted such that the desired high internal stress level may be obtained and also in view of gap filling capabilities such that a space 157 between neighboring transistor elements, i.e., the corresponding gate electrode structures, may be reliably filled with the material of the layer 130. A reliable fill of the space 157 is not only important in view of the overall strain-inducing mechanism, since an enhanced strain may be generated in the channel region 153 when an increased amount of a stressed material is sufficiently close to the channel region 153, but also in view of the further manufacturing processes in which a further dielectric material may have to be deposited in a highly stressed state, followed by the deposition of an interlayer dielectric material, which in turn would be patterned in order to provide contact elements to the transistor elements 150A, 150B. During the patterning process, deposition-related irregularities, such as voids, may preferably be created at critical areas, such as area 132, and may represent a main contribution to significant yield losses in the formation of contact elements in sophisticated semiconductor devices. Thus, during the deposition of the layer 130, the aspect ratio of the spacing 157 may require an adequate adaptation of the layer thickness, thereby reducing the amount of highly stressed material that may be positioned in the vicinity of the transistors 150A. Additionally, the aspect ratio of the spacing 157 may even be increased by providing the etch stop layer 131 with a moderately high thickness so as to ensure integrity of the transistor 150B in the subsequent patterning of the layer 130.

FIG. 1b schematically illustrates the semiconductor device 100 in an advanced manufacturing stage in which an etch mask 103 is formed above the transistors 150A, while exposing the transistor 150B to a plasma assisted etch ambient 104. Thus, at a final phase of the etch process 104, the etch stop layer 131 may be exposed and may also be subject to a certain degree of material removal, however, at a significantly reduced removal rate, wherein a certain amount of over-etch time may be applied so as to reliably remove unwanted portions of the layer 130 across the entire substrate 101. Consequently, by providing a sufficient thickness for the etch stop layer 131, a high degree of integrity of the transistor 150B may be achieved during the etch process 104 thereby, however, reducing the strain transfer mechanism in the transistors 150A since a thickness thereof may have to be adapted to the resulting surface topography after the deposition of the layer 131. Thus, upon further device scaling, the ratio between the stop material and highly stressed dielectric material in the vicinity of the transistors may further increase, thereby even further reducing the overall efficiency of strain-inducing mechanisms. Consequently, during the formation of interlayer dielectric material above the completed basic transistor configuration, a plurality of patterning processes have to be performed on the basis of plasma assisted etch techniques, wherein the provision of an etch stop material may increasingly reduce the overall performance of transistor elements, in particular when strain-inducing mechanisms are considered.

The present disclosure is directed to various methods and devices that may avoid, or at least reduce, the effects of one or more of the problems identified above.

### SUMMARY OF THE DISCLOSURE

The following presents a simplified summary of the disclosure in order to provide a basic understanding of some aspects disclosed herein. This summary is not an exhaustive overview, and it is not intended to identify key or critical elements of the invention or to delineate the scope of the invention. Its sole purpose is to present some concepts in a simplified form as a prelude to the more detailed description that is discussed later.

Generally, the present disclosure relates to semiconductor devices and methods for forming the same in which enhanced etch stop capabilities may be obtained on the basis of a reduced layer thickness by using high-k dielectric materials in the contact level of the semiconductor devices. In illustrative aspects disclosed herein, high-k dielectric material may be used as efficient etch stop material during patterning of semiconductor devices in contact levels by exploiting characteristics of high-k dielectric materials that a volatile etch byproduct may not be generated during well-established anisotropic etch recipes which are typically used in standard CMOS manufacturing techniques. For this reason, a reduced thickness may be sufficient for reliably stopping a plasma-assisted etch front, which may therefore enable the deposition of a subsequent material on the basis of less increased aspect ratios. In some illustrative aspects, a reduced thickness of the etch stop material may be employed in combination with strain-inducing mechanisms in the contact level of the semiconductor device, thereby providing the potential for depositing an increased amount of highly stressed dielectric material above the basic transistor configuration for a given design of the semiconductor device under consideration.

One illustrative method disclosed herein comprises forming a high-k dielectric layer above a first transistor and a second transistor of a semiconductor device. The method additionally comprises forming a first strain-inducing layer on the high-k dielectric layer in order to generate a strain in a channel region of the first and second transistors. Furthermore, the method comprises removing a portion of the first strain-inducing layer from above the second transistor by using the high-k dielectric layer as an etch stop material.

A further illustrative method disclosed herein comprises forming a contact opening in an interlayer dielectric material that is formed above a transistor of a semiconductor device by forming one or more deposition processes and one or more etch processes, wherein the interlayer dielectric material comprises a high-k dielectric material layer. Additionally, the method comprises using the high-k dielectric material layer as an etch stop material during at least one of the one or more etch processes.

One illustrative semiconductor device disclosed herein comprises a transistor formed above a substrate and an interlayer dielectric material enclosing the transistor, wherein the interlayer dielectric material comprises a layer of high-k dielectric material. Additionally, the semiconductor device comprises a contact element extending through the interlayer dielectric material and into a contact area of the transistor.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1b schematically illustrate cross-sectional views of a semiconductor device during various manufacturing stages in forming stress-inducing material above the basic transistor configuration according to a conventional process strategy;

FIGS. 2a-2b schematically illustrate cross-sectional views of a transistor element during various manufacturing stages in forming a contact level of a transistor element using a high-k dielectric material as an etch stop material according to illustrative embodiments; and

FIGS. 3a-3g schematically illustrate cross-sectional views of a semiconductor device during various manufacturing stages in forming stress-inducing layers of different types of internal stress level above transistors of different conductivity type on the basis of one or more high-k dielectric etch stop materials according to still further illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the present disclosure addresses the problem of patterning materials in the contact level of sophisticated semiconductor devices where the characteristics of conventional etch stop materials, such as silicon dioxide, silicon nitride and the like, may result in reduced performance of transistor elements, since a required thickness for providing the necessary etch stop capabilities may negatively affect transistor characteristics or, when reducing the thickness of the etch stop material, negatively affecting further processing of the device. In view of this situation, the present disclosure relates to techniques and semiconductor devices in which high-k dielectric materials may be used as efficient etch stop materials, wherein any of these materials may have significantly different etch characteristics in view of a plurality of plasma-assisted etch recipes as are typically used during processing of sophisticated semiconductor devices. For example, tantalum oxide (Ta₂O₅), strontium titanium oxide (SrTiO₃), hafnium oxide (HfO₂), hafnium silicon oxide, zirconium oxide (ZrO₂), may be increasingly used, for instance, for gate dielectrics and the like. In one illustrative embodiment, hafnium oxide may be used as a highly efficient etch stop material due to its characteristic to substantially not create volatile byproducts during well-established fluorine and chlorine-based plasma-assisted etch processes, which may typically be used for etching silicon nitride materials and the like.

It should be appreciated that, in the context of the present disclosure, a high-k dielectric material is to be understood as a dielectric material having a dielectric constant of approximately 10 or higher.

By exploiting the reduced removal rate and high stability of the high-k dielectric material during formation of the contact level of semiconductor devices, significant advantages with respect to the overall manufacturing sequence and/or the performance of the semiconductor devices may be achieved. For instance, providing a thin yet highly efficient etch stop material may allow providing a subsequent material in view of its deposition characteristics, rather than having to provide a moderately thick etch stop material as may be required for patterning of actual interlayer dielectric material. That is, since a reliable control of the etch process for contact openings may be based on a high-k dielectric material, a subsequent material may be formed with high gap filling capabilities so as to relax the overall surface topography for sophisticated semiconductor devices, thereby enhancing the overall process flow. In other cases, the amount of stressed dielectric material may be increased for the respective transistor element without sacrificing integrity of the basic transistor structures during the patterning of stressed dielectric materials of different internal stress levels. Consequently, the stress-inducing mechanisms may be employed during the further scaling of device dimensions while not unduly reducing the overall efficiency of these mechanisms.

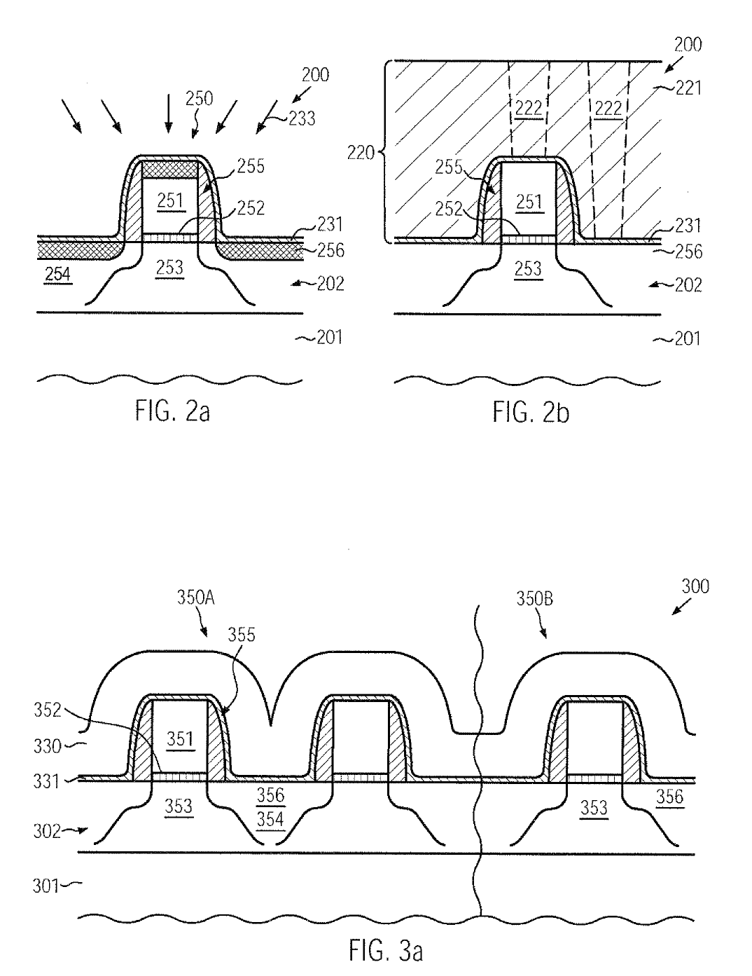

FIG. 2a schematically illustrates a cross-sectional view of a semiconductor device 200 in an advanced manufacturing stage at which an interlayer dielectric material is to be formed and patterned. The semiconductor device 200 may comprise a substrate 201 which may be provided in the form of any appropriate carrier material for forming thereabove a semiconductor layer 202 which may represent any appropriate material for forming therein and thereabove a transistor 250. The semiconductor layer 202 may represent a silicon-based material since many complex integrated circuits may be formed on the basis of silicon, the characteristics of which, in view of charge carrier mobility, may be modified by creating a respective strain, as previously explained. It should be appreciated, however, that, in other embodiments, any other semiconductor materials may be used, such as germanium, mixtures of silicon and germanium, silicon and carbon or any other semiconductor compounds. Furthermore, a buried insulating layer (not shown) may be positioned between the substrate 201 and the semiconductor layer 202, at least in some device areas of the device 200, depending on the desired overall transistor architecture.

In the manufacturing stage shown, the transistor 250 may comprise a gate electrode 251, which may be separated from a channel region 253 by a gate insulation layer 252. The gate electrode 251 may be comprised of any appropriate material, such as polysilicon, a metal-containing material, a mixture of polysilicon and a metal, wherein the metal may extend down to the insulation layer 252, and the like. Similarly, the gate insulation layer 252 may be comprised of any appropriate material, such as silicon dioxide, silicon nitride, silicon oxynitride and the like. In sophisticated applications, the gate insulation layer 252 may comprise a high-k dielectric material, for instance in the form as specified above. Furthermore, the transistor 250 may comprise drain and source regions 254 having any appropriate vertical and lateral dopant profile as may be required for enhanced performance of the transistor 250. Furthermore, a spacer structure 255 may be provided at sidewalls of the gate electrode 251 with any appropriate configuration. Additionally, if required, contact areas 256 in the drain and source regions 254 may comprise metal, for instance in the form of metal silicide to reduce contact resistance. Similarly, metal silicide 256 may also be formed in the gate electrode 251 when including a portion comprised of polysilicon.

Moreover, the semiconductor device 200 may further comprise a high-k dielectric layer 231 that is formed above the transistor 250. In one illustrative embodiment, the high-k dielectric layer 231, which may act as an etch stop layer during the further processing of the device 200, may be formed on the transistor 250, that is, the layer 231 may be in contact with the contact areas 256, which may be comprised of, for instance, a metal silicide, as previously explained. In other illustrative embodiments, the high-k dielectric layer 231 may be formed at any appropriate position within an interlayer dielectric material. One or more further high-k dielectric layers may be provided, as will be explained later on. In one illustrative embodiment, the high-k dielectric layer 231 may have a thickness of approximately 10 nm and less, while, in some applications, the thickness of the layer 231 may be approximately 5 nm and less. The layer 231 may be comprised of any appropriate material, as previously explained, while, in one illustrative embodiment, the layer 231 comprises hafnium, for instance in the form of hafnium oxide (HfO₂).

The semiconductor device 200 as shown in FIG. 2a may be formed on the basis of the following processes. After defining respective isolation structures (not shown), for instance by lithography, deposition and planarization techniques, the gate insulation layer 252 and the gate electrode 251 may be formed by oxidation and/or deposition followed by a patterning process using advanced lithography techniques. Thereafter, the drain and source regions 254, or at least a portion thereof, may be defined by ion implantation, wherein respective portions of the spacer structure 255 may act as an efficient implantation mask in combination with the gate electrode 251. After annealing the device 200 to activate dopants and re-crystallize damaged areas, the contact areas 256, for instance in the form of metal silicide, may be formed on the basis of well-established recipes. A deposition process 233 may be performed on the basis of any appropriate technique, such as chemical vapor deposition (CVD), physical vapor deposition (PVD) and the like, to provide the high-k dielectric material with an appropriate thickness, for instance in the above-specified range, wherein typically a significant reduced value may be used compared to conventional dielectric etch stop materials, such as silicon dioxide, silicon nitride and the like. Thus, when forming the layer 231 with reduced thickness, highly conformal deposition behavior may be obtained, thereby reducing the influence of the layer 231 with respect to the resulting surface topography of the device 200, which may relax any constraints in view of the deposition behavior of subsequent deposition processes to be performed to deposit further dielectric material. For example, in some illustrative embodiments, further dielectric material may be formed on the basis of a deposition technique providing enhanced gap fill capabilities without requiring additional etch stop materials, since the layer 231, although provided with reduced thickness, may provide sufficient etch stop capabilities during patterning of contact openings.

FIG. 2b schematically illustrates the semiconductor device 200 in an advanced manufacturing stage, in which further dielectric material 221 may be formed on the etch stop layer 231, wherein the material 221 may comprise a plurality of different materials, depending on the desired configuration of an interlayer dielectric material 220 defined by etch stop material 231 and the material 221. For example, the material 221 may be comprised of silicon dioxide for efficient deposition techniques with high gap filling capabilities, for instance, such as plasma-enhanced CVD and sub-atmospheric CVD on the basis of TEOS. In other cases, the material 221 may be provided with increased flexibility in view of deposition techniques and material composition, since the desired material may be positioned close to the transistor 250 without having to provide etch stop capabilities with respect to the patterning of the material 221. For example, any appropriate strain-inducing materials, such as silicon nitride, nitrogen-containing silicon carbide, highly stressed silicon dioxide and the like, may be provided within the material 221 at different device areas within the material 221, since any potential differences in the etch characteristics may be “compensated for” by the highly efficient etch stop material 231. That is, in some illustrative embodiments, a highly stressed silicon dioxide material may be positioned close to one transistor, while silicon nitride material may be positioned close to another transistor, substantially without affecting the overall uniformity during a subsequent patterning process for forming contact openings 222, as indicated by the dashed lines.

Thus, after the deposition of the dielectric material 221, appropriate lithography techniques may be employed to form a mask above the interlayer dielectric material 220 and etch through the material 221, while using etch stop layer 231 as an efficient etch stop due to the reduced formation of volatile byproducts, as previously explained.

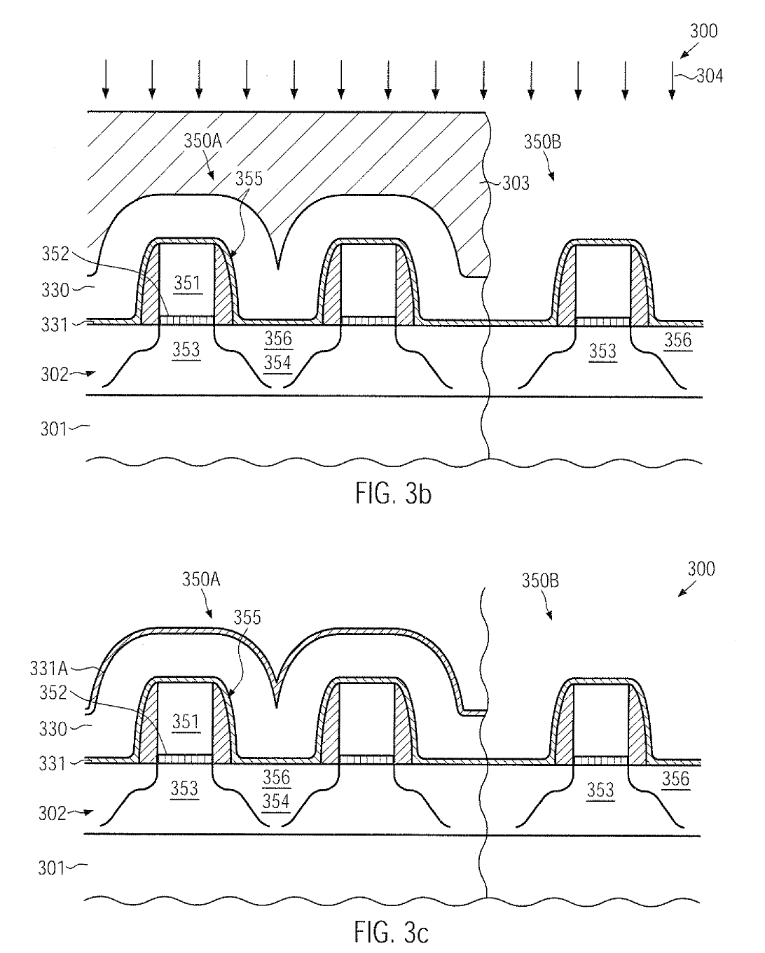

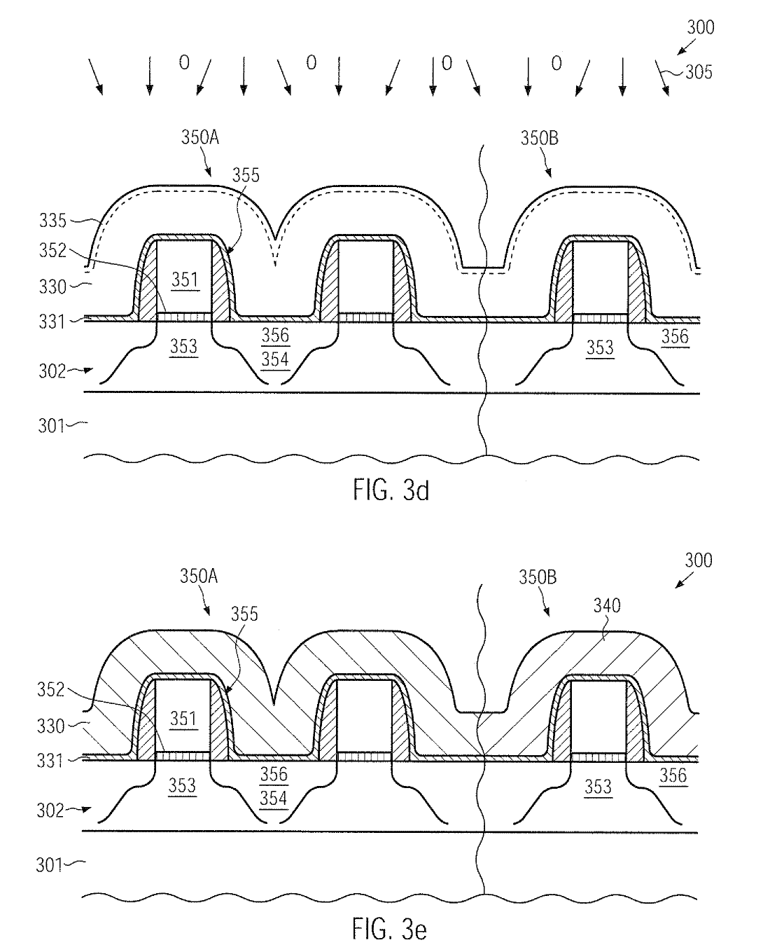

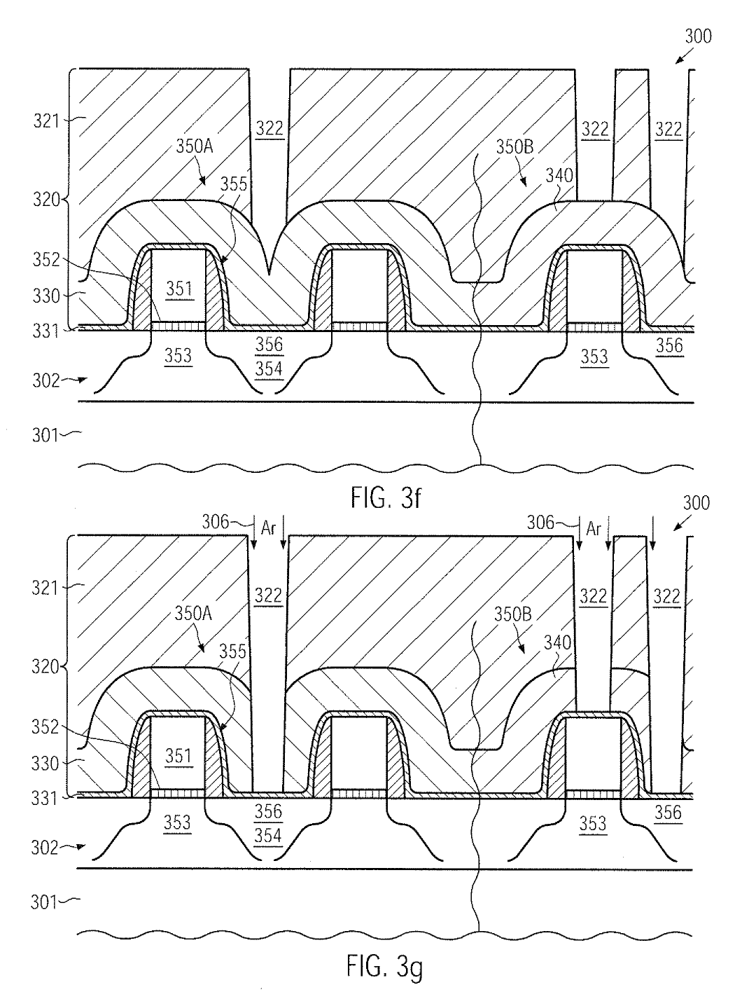

With reference to FIGS. 3a-3g, further illustrative embodiments will now be described in which strain-inducing materials may be formed in the contact level for different types of transistors on the basis of a high-k dielectric etch stop material.

FIG. 3a schematically illustrates a cross-sectional view of a semiconductor device 300 comprising a substrate 301 above which may be formed a semiconductor layer 302. With respect to these components, the same criteria apply as previously explained with reference to the devices 100 and 200. Furthermore, the device 300 may comprise one or more transistors 350A which may be representative of the same or different conductivity type. That is, one of the transistors 350A may represent a P-channel transistor while the other one may represent an N-channel transistor with an appropriate isolation structure (not shown) formed between these devices. In the embodiment shown, it may be assumed that the transistors 350A may represent transistors of the same conductivity type which are formed in a device area by high packing density, such as a RAM area, as is also described with reference to the device 100. On the other hand, the one or more transistors 350B may represent a transistor which may require a different strain mechanism compared to the transistors 350A. For instance, the transistor 350B may represent a P-channel transistor while the transistors 350A may represent N-channel transistors. In the manufacturing stage shown, the transistors 350A, 350B may be substantially completed and may therefore comprise a gate electrode 351, which may be separated from a channel region 353 by a gate insulation layer 352. With respect to the gate electrode 351 and the gate insulation layer 352, the same criteria apply as previously explained with reference to the devices 100 and 200. Furthermore, drain and source regions 354 may be formed in the semiconductor layer 302 while also, if required, a spacer structure 355 may be formed on sidewalls of the gate electrode 351. If required, a metal material may be provided in contact areas 356. With respect to any dimensions of the transistors 350A, 350B, the same criteria apply as previously explained with reference to the device 100. That is, the transistors 350A, 350B may have a gate length of approximately 50 nm and less, while also a distance between neighboring gate electrodes of the closely spaced transistors 350A may be several hundred nanometers and less.

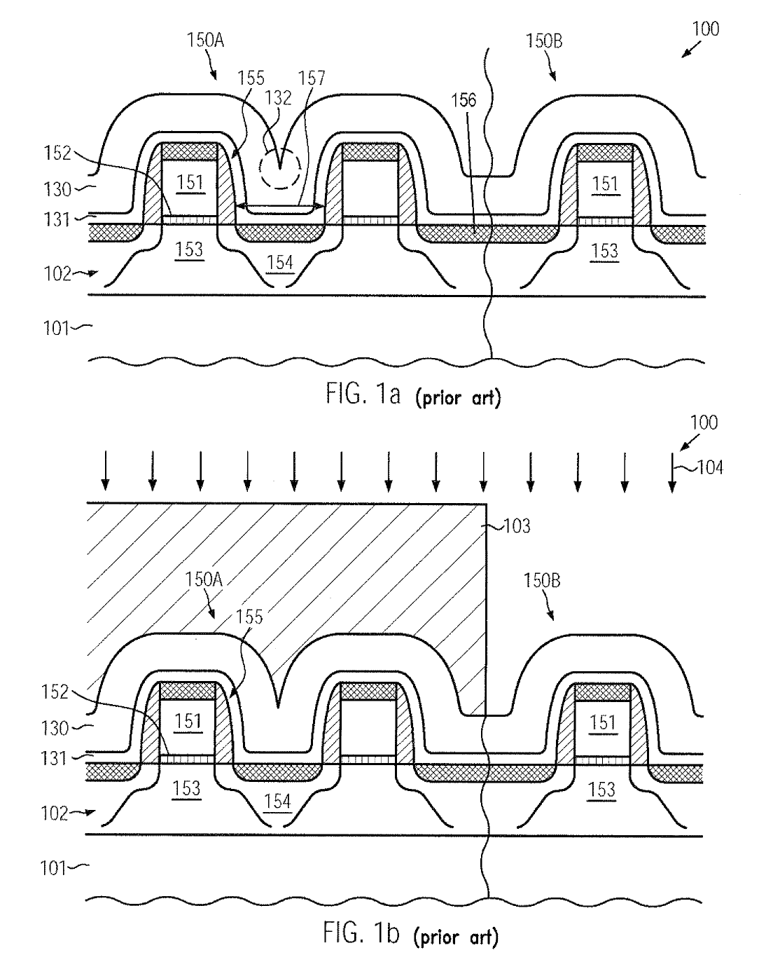

The transistors 350A, 350B may be formed on the basis of process techniques as are, for instance, described with reference to the semiconductor device 200, wherein the respective design rule may result in sophisticated surface topography created by the gate electrodes 351 and the close proximity of the transistors 350A. Thereafter, an etch stop layer 331 may be formed which may have similar characteristics as previously described with reference to the high-k dielectric layer 231. Hence, the etch stop layer 331 may be comprised of any appropriate high-k dielectric material having a high etch resistance with respect to well-established plasma-assisted etch recipes. In some illustrative embodiments, the layer 331 may comprise hafnium, for instance in the form of hafnium oxide. A thickness of the layer 331 may, in some illustrative embodiments, be approximately 10 nm and less, wherein it should be appreciated that, if desired, a greater thickness may be used, while, in other embodiments, an even further reduced thickness, for instance 5 nm, 3 nm and less, may be used. The layer 331 may be formed on the basis of any appropriate deposition technique, such as CVD and the like. Next, a first strain-inducing layer 330, which may be comprised of any appropriate material, such as silicon nitride, nitrogen-containing silicon carbide, silicon dioxide and the like, may be formed above the transistors 350A, 350B. In the embodiment shown, it may be assumed that the layer 330 may be provided with a high internal stress that is appropriate for enhancing performance of the transistors 350A, while possibly negatively affecting performance of the transistor 350B. It should be appreciated, however, that the layer 330 may have an internal stress level configured to enhance performance of the transistor 350B according to other cases. As previously explained, the deposition parameters for forming the layer 330 may have to be selected such that the desired internal stress level may be obtained, while also the gap fill capabilities may be respected in order to provide the layer 330 substantially without deposition-related irregularities, such as voids and the like. Due to the reduced thickness of the etch stop layer 331, the layer 330 may be provided by less demanding constraints, which may enable the deposition of an increased thickness compared to a conventional strategy, as is explained with reference to FIGS. 1a-1b, thereby providing increased amounts of highly stressed dielectric material in the vicinity of the transistors 350A, without increasing the probability of causing additional yield losses.

FIG. 3b schematically illustrates the semiconductor device 300 in an advanced manufacturing stage. As illustrated, an etch mask 303 may cover the transistors 350A, while exposing the transistor 350B to a plasma-assisted etch ambient 304 designed to etch the portion of the layer 330 located above the transistor 350B. The superior etch stop capabilities of the high-k dielectric material in the layer 331 may thus maintain integrity of the underlying transistor areas of the device 300 while nevertheless providing sufficient process margin during the final phase of the etch process 304.

FIG. 3c schematically illustrates the semiconductor device 300 according to further illustrative embodiments in which a further high-k dielectric layer 331A may be formed on the strain-inducing layer 330. For instance, the layer 331A may be comprised of the same material as the layer 331, while, in other cases, a different high-k dielectric material may be used wherein a thickness of the layer 331A may also be in the range of approximately 10 nm or less. For example, the layer 331A may be formed at the end of the etch process 304 and after the removal of the etch mask 303, thereby also depositing the layer 331A above the exposed portion of the layer 331 in the transistor 350B. In other illustrative embodiments, as shown, the layer 331A may have been formed after depositing the layer 330 and prior to performing the etch process 304. In this case, the etch process 304 may comprise an appropriate removal process, for instance on the basis of a sputter etch process, in which any appropriate heavy species, such as argon, may be directed to the exposed surface portion and may physically remove the material of the layer 331A. Thereafter, a conventional etch recipe may be used for removing the exposed portion of the layer 330, as previously explained. Consequently, the high-k dielectric material 331A may act as an efficient yet thin etch stop material during the further processing of the device 300.

FIG. 3d schematically illustrates the semiconductor device 300 after the deposition of the layer 330 according to still further illustrative embodiments. As shown, a plasma-assisted oxidation process 305 may be performed to convert a surface area of the layer 330 into an oxidized portion, for instance comprised of silicon dioxide, wherein a thickness may be several nanometers, depending on the parameters of the plasma ambient 305. Hence, also in this case, an efficient etch stop or etch control layer 335 may be provided for the further processing of the device 300. In still other illustrative embodiments, the plasma treatment 305 may be performed after the etch process 304 and the removal of the etch mask 303, wherein the exposed portion of the etch stop layer 331 may provide the desired integrity of the transistor 350B.

Thereafter, the further processing may be continued, for instance, by the deposition of a further strain-inducing material, which may have an internal stress level so as to enhance performance of the transistor 350B.

FIG. 3e schematically illustrates the semiconductor device 300 in a manufacturing stage where a second strain-inducing layer 340 is selectively provided above the transistor 350B. For this purpose, the layer 340 may be deposited and may be selectively removed from above the transistors 350A, wherein, in some illustrative embodiments, the additional etch stop or etch control layers 331A (FIG. 3c) or 335 (FIG. 3d) may be used for controlling the respective etch process and provide a moderately thin etch stop or etch control layer, for instance in the form of the layers 331A, 335, which result in reduced deposition-related surface irregularities, since the deposition of the material 340 may also have to be performed under sophisticated surface topographies, wherein, in particular, the removal process above the transistors 350A may result in irregularities which may cause contact failure in a later manufacturing stage. Thus, also in this case, a reduced thickness of an etch stop material, such as the layers 331A, 335, may provide enhanced overall process efficiency.

FIG. 3f schematically illustrates the semiconductor device 300 in a further advanced manufacturing stage. As shown, a further dielectric material 321 may be formed above the layers 330 and 340, thereby defining, in combination with the layers 330, 340 and the high-k dielectric etch stop material 331, an interlayer dielectric material 320. It should be appreciated that the material 321 may comprise two or more different materials and also additional etch stop or etch control materials may be present, for instance in the form of the layers 331A, 335, which may be locally provided above the transistors 350A. Furthermore, first portions of contact openings 322 may be formed in the material 321, wherein a portion 322 may extend in a more or less pronounced degree into the layers 330, 340, depending on the overall material compositions of the materials 322, 330 and 340. That is, in some cases, one of the layers or both layers 330, 340 may have similar etch characteristics, thereby providing reduced etch stop capabilities which, however, may be acceptable since integrity of the transistor devices may be ensured by the high-k dielectric material 331. Thus, contrary to conventional approaches, a high degree of flexibility may be provided in selecting appropriate materials for the layers 330, 340 and 321. The material 321 and the contact openings 322 may be formed on the basis of any appropriate deposition and patterning regime, as is also previously explained.

FIG. 3g schematically illustrates the semiconductor device 300 in a further advanced manufacturing stage. As shown, the openings 322 may extend down to the high-k dielectric 331, which may be accomplished on the basis of any appropriate recipe, for instance designed to etch through silicon nitride material, when the layers 330, 340 are substantially comprised of stressed silicon nitride material. In other cases, as previously explained, the openings 322 may be formed in a single etch sequence so as to etch through the material 321 and the layers 330, 340 on the basis of a substantially non-selective etch recipe. Furthermore, the device 300 is subjected to an etch process 306 designed to open the high-k dielectric etch stop material 331 in order to extend the openings 322 down to the contact areas 356, which may be positioned at different height levels, for instance corresponding to the height of the gate electrodes 351 and the drain and source regions 354. The etch process 306 may be provided in the form of a sputter etch process in which an appropriate species, such as argon, may be used to remove exposed portions of the high-k dielectric material 331. During the sputter process 306, the respective species may be released into the sputter ambient or may re-sputter at sidewalls of contact openings 322, which may, however, not unduly affect the further processing. It should be appreciated that the process 306 may be performed on the basis of an etch mask, if desired, while, in other cases, due to the reduced thickness of the layer 331, any etch damage in the material 321 may be acceptable. Thereafter, the contact openings 322 may be filled with a desired conductive material, such as tungsten, copper, aluminum and the like, depending on the overall process strategy, wherein typically an appropriate barrier material may also be provided. For this purpose, well-established process techniques may be used.

As a result, the present disclosure provides semiconductor devices and techniques in which high-k dielectric materials may be used for forming a contact level of a semiconductor device, i.e., an interlayer dielectric material and respective contact openings wherein the high etch capabilities of the high-k dielectric materials allow the provision of etch stop materials with reduced thickness compared to conventional strategies, thereby enhancing deposition of subsequent materials and providing increased flexibility in providing interlayer dielectric materials. In some illustrative embodiments, a high-k dielectric material comprising hafnium may be used as an efficient etch stop layer.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a high-k dielectric layer above a first transistor and a second transistor of a semiconductor device;
forming a first strain-inducing layer on said high-k dielectric layer, said first strain-inducing layer generating strain in a channel region of said first and second transistors; and
removing a portion of said first strain-inducing layer from above said second transistor by using said high-k dielectric layer as an etch stop material.

2. The method of claim 1, wherein forming said high-k dielectric layer comprises depositing said high-k dielectric layer with a thickness of approximately 10 nm or less.

3. The method of claim 1, wherein said high-k dielectric layer comprises at least one of hafnium, tantalum, strontium and zirconium.

4. The method of claim 3, wherein said high-k dielectric layer comprises hafnium oxide.

5. The method of claim 1, further comprising forming an opening in said first strain-inducing layer and removing a portion of said high-k dielectric layer exposed by said opening by performing a sputter etch process.

6. The method of claim 1, further comprising forming a second high-k dielectric layer on said first strain-inducing layer prior to removing said portion of the first strain-inducing layer.

7. The method of claim 6, further comprising forming a second strain-inducing layer above said first and second transistors and removing a portion of said second strain-inducing layer from above said first transistor by using said second high-k dielectric layer as an etch stop.

8. The method of claim 6, wherein a thickness of said second high-k dielectric layer is 10 nm or less.

9. The method of claim 6, wherein said second high-k dielectric layer comprises at least one of hafnium, tantalum, strontium and zirconium.

10. A method, comprising:
forming a contact opening in an interlayer dielectric material formed above a transistor of a semiconductor device by performing one or more deposition processes and one or more etch processes, said interlayer dielectric material comprising a high-k dielectric material layer; and
using said high-k dielectric material layer as an etch stop material during at least one of said one or more etch processes.

11. The method of claim 10, further comprising forming said high-k dielectric material layer on said transistor and depositing one or more further dielectric materials so as to form said interlayer dielectric material.

12. The method of claim 10, wherein performing one or more etch processes comprises performing a sputter etch process to etch through said high-k dielectric material layer.

13. The method of claim 10, further comprising forming a strain-inducing layer as part of said interlayer dielectric material, said strain-inducing layer generating strain in a channel region of said transistor.

14. The method of claim 13, further comprising removing a portion of said strain-inducing layer by said at least one of said one or more etch processes.

15. The method of claim 13, further comprising forming a second strain-inducing layer as a part of said interlayer dielectric material, said second strain-inducing layer generating a different type of strain compared to said first strain-inducing layer.

16. The method of claim 15, further comprising forming a second high-k dielectric material layer and using said second high-k dielectric material layer as an etch control material for patterning said second strain-inducing layer during one of said one or more etch processes.

17. A semiconductor device, comprising:
a transistor formed above a substrate;
an interlayer dielectric material formed above said transistor, said interlayer dielectric material comprising a layer of a high-k dielectric material; and
a contact element extending through said interlayer dielectric material and into a contact area of said transistor.

18. The semiconductor device of claim 17, wherein a thickness of said layer of high-k dielectric material is approximately 10 nm or less.

19. The semiconductor device of claim 17, wherein said layer of high-k dielectric material is formed on said contact area.

20. The semiconductor device of claim 17, wherein said interlayer dielectric material comprises a strain-inducing layer formed above said transistor so as to induce a strain in a channel region of said transistor.

21. The semiconductor device of claim 17, wherein said layer of high-k dielectric material comprises at least one of hafnium, tantalum, strontium and zirconium.

22. The semiconductor device of claim 21, wherein said layer of dielectric material comprises hafnium.

23. The semiconductor device of claim 20, further comprising a second transistor and a second strain-inducing layer formed above said second transistor, said second strain-inducing layer generating a second type of strain other than said strain generated by said strain-inducing layer.

24. The semiconductor device of claim 23, wherein said layer of high-k dielectric material is formed below said strain-inducing layer and said second strain-inducing layer.

25. The semiconductor device of claim 17, wherein a gate length of said transistor is approximately 50 nm or less.
